(19) United States
(12) Patent Application Publication
(10) Pub. No.: US 2010/0006907 A1
(43) Pub. Date: Jan. 14, 2010

(54) SEMICONDUCTOR DEVICE AND METHOD OF MANUFACTURING THE SAME

(76) Inventor: Hiroshi ITOKAWA, Yokohama-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/494,611

(22) Filed: Jun. 30, 2009

(30) Foreign Application Priority Data
Jul. 9, 2008 (JP) 2008-178795

(51) Int. Cl. H01L 29/78; H01L 21/336

(52) U.S. Cl. 257/288; 438/296; 257/E29.255; 257/E21.409

(57) ABSTRACT

In a FET using a SiGe film as a channel region, dispersion of the Ge concentration in the SiGe film and dispersion of the film thickness of the SiGe film are suppressed.

The FET includes:
a substrate 101 having silicon as its main component;
a trench 104 formed on a substrate 101 formed so as to surround an element region;
a SiGe film 107 formed on the substrate 101 in the element region; and
a silicon migration prevention layer 106 which is formed on a part 104a of a side wall of the trench 104 and which contains at least one of nitrogen and carbon.

### CROSS-REFERENCE TO RELATED APPLICATION

This application is based upon and claims the benefit of priority from prior Japanese Patent Application No. 2003-178795, filed on Jul. 9, 2008. The entire contents of which are incorporated herein by reference.

### BACKGROUND OF THE INVENTION

1. Field of the Invention

The present invention relates to a semiconductor device, for example, a field effect transistor using the strained silicon technique and a method of manufacturing the semiconductor device.

2. Background Art

Recently, size shrinking of semiconductors has been promoted. Ultra size shrunk/ultra high speed semiconductor devices having a gate length of 65 nm or less are now being researched and developed. In field effect transistors (FETs) among such ultra size shrunk/ultra high speed semiconductor devices, the area of a channel region located right under a gate electrode is very small as compared with the conventional FET. Therefore, it is known that mobility of carriers (electrons or holes) traveling a channel region is greatly affected by stress applied to the channel region. Attempts to improve the operation speed of semiconductor devices by optimizing the stress applied to the channel region are now being conducted vigorously.

For example, as described in Japanese Patent Laid-open Publication No. 1998-92947, it is known to increase the carrier mobility and improve the FET performance by using a technique for forming a biaxial compressive strained SiGe thin film in a channel region of a silicon substrate.

A next generation FET having a gate structure obtained by stacking a metal gate electrode and a high dielectric constant: insulating film (high-k film) is also being researched. As one of methods for controlling a threshold voltage of this FET, a method of utilizing the SiGe film formed in the channel region is being studied. The work function of SiGe can he changed by changing the Ge concentration in the SiGe film. By utilizing this to control the difference between the work function of SiGe and the work function of the metal gate electrode, it becomes possible to control the threshold voltage. As an advantage of this method, it can be mentioned that the range of choice of a metal material serving as the gate electrode is widened because the threshold voltage can he controlled comparatively easily by changing the composition ratio of SiGe.

### SUMMARY OF THE INVENTION

According to one aspect, the present invention provides a semiconductor device including:

a substrate having silicon as a main component;

a trench which is formed in the substrate in a thickness direction, which partitions off an element region where a semiconductor element is formed, and which has a side wall surface connected to the surface of the substrate in the element region;

an element isolation insulating film embedded in the trench up to a middle of the trench;

a silicon migration prevention layer which exists between the surface of the substrate in the element region and the side wall surface covered by the element isolation insulating film, and which contains at least one of nitrogen and carbon; and

a SiGe film formed on the substrate in the element region.

According to another aspect, the present invention provides a semiconductor device manufacturing method including:

forming a mask material on a substrate having silicon as a main component;

patterning the mask material;

forming a trench which partitions off an element region, by etching the substrate with the mask material used as a mask;

forming an element isolation insulating film by embedding an insulating film into the trench;

exposing a part of a side wall of the trench by etching the element isolation insulating film;

forming a silicon migration prevention layer embedded in the part of the side wall of the trench by nitrifying and/or carbonizing the exposed part of the side wall of the trench;

removing the mask material and then reducing a native oxide film on a surface of the substrate by hydrogen annealing; and

then epitaxially growing a SiGe film on the substrate in the element region.

### BRIEF DESCRIPTION OF THE DRAWINGS

FIG. 1A is a sectional view showing a manufacturing process of a semiconductor device according to a first embodiment;

FIG. 1B is a sectional view showing a manufacturing process of the semiconductor device according to the first embodiment, subsequent to that shown in FIG. 1A;

FIG. 1C is a sectional view showing a manufacturing process of the semiconductor device according to the first embodiment, subsequent to that shown in FIG. 1B;

FIG. 1D is a sectional view showing a manufacturing process of the semiconductor device according to the first embodiment, subsequent to that shown in FIG. 1C;

FIG. 1E is a sectional view showing a manufacturing process of the semiconductor device according to the first embodiment, subsequent to that shown in FIG. 1D;

FIG. 1F is a sectional view showing a manufacturing process of the semiconductor device according to the first embodiment, subsequent to that shown in FIG. 1E;

FIG. 1G is a sectional view showing a manufacturing process of the semiconductor device according to the first embodiment, subsequent to that shown in FIG. 1F;

FIG. 1H is a sectional view showing a manufacturing process of the semiconductor device according to the first embodiment, subsequent to that shown in FIG. 1G;

FIG. 1I is a sectional view of the semiconductor device according to the first embodiment;

FIG. 2A is a sectional view showing a manufacturing process of a semiconductor device according to a second embodiment;

FIG. 2B is a sectional view showing a manufacturing process of the semiconductor device according to the second embodiment, subsequent to that shown in FIG. 2A;

FIG. 2C is a sectional view showing a manufacturing process of the semiconductor device according to the second embodiment, subsequent to that shown in FIG. 2B;

FIG. 2D is a sectional view showing a manufacturing process of the semiconductor device according to the second embodiment, subsequent to that shown in FIG. 2G;

FIG. 2E is a sectional view showing a manufacturing process of the semiconductor device according to the second embodiment, subsequent to that shown in FIG. 2D;

FIG. 2F is a sectional view showing a manufacturing process of the semiconductor device according to the second embodiment, subsequent to that shown in FIG. 2E;

FIG. 2G is a sectional view showing a manufacturing process of the semiconductor device according to the second embodiment, subsequent to that shown in FIG. 2F;

FIG. 2H is a sectional view showing a manufacturing process of the semiconductor device according to the second embodiment, subsequent to that shown in FIG. 2G;

FIG. 2I is a sectional view of the semiconductor device according to the second embodiment; and

FIG. 3 shows a TEM image of a section obtained near an STI trench after a SiGe film is formed.

### DESCRIPTION OF THE EMBODIMENTS

Prior to description of embodiments of the present invention, how the present inventor came to make the present invention will now be described.

The conventional SiGe channel forming technique using epitaxial growth has problems described below. At the time of opening of a mask material (SiO₂) in a FET element region and preprocessing of epitaxial growth of the SiGe film, etching processing is executed. At this time, a silicon oxide film embedded in an STI trench which partitions off the FET element region is etched together. As a result, a sinking part called divot is generated, and a part of side walls of the STI trench is exposed. Thereafter, hydrogen annealing is conducted to reduce and remove a native oxide film formed of, for example, a silicon oxide on the substrate surface before forming a SiGe film. Since dangling bonds of Si atoms on the substrate surface are terminated by hydrogen atoms at this time, the Si atoms become apt to migrate. As a result, Si atoms at ends of the FET element region migrate to the above-described divot. Accordingly, the plane orientation of the region where Si atoms have migrated deviates from the ordinary plane orientation. In the region where the plane orientation has deviated, therefore, it becomes impossible to cause normal epitaxial growth of the SiGe film. As a result, dispersion occurs in the Ge concentration and growth film thickness in the SiGe film formed near the FET element region end. There is concern that dispersion will occur in the threshold voltage of FETs because of the dispersion in the composition and the growth film thickness of the SiGe film. In addition, if the gate insulating film is an insulating film formed of a high dielectric constant material containing hafnium (Hf), then there is concern for poor operation of the FET element caused by an abnormal reaction between hafnium and germanium contained in the SiGe film.

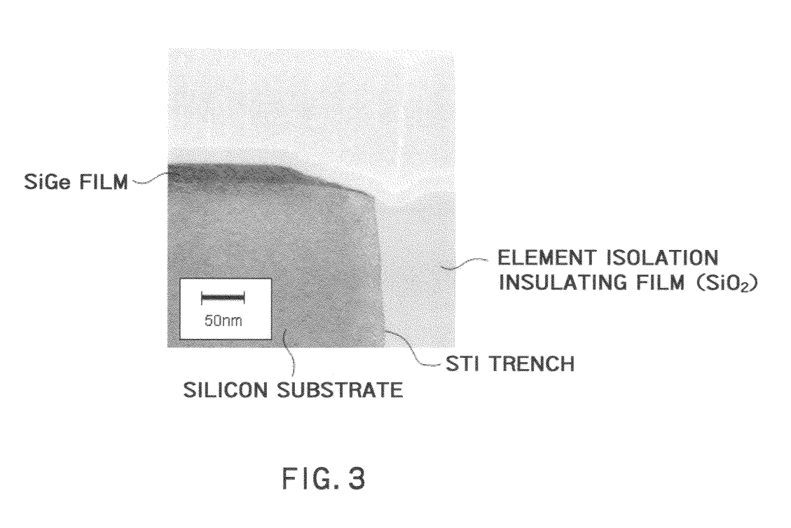

FIG. 3 shows a TEM image of a section obtained near a FET element region end after a SiGe film is formed. As known from FIG. 3, the film thickness of the SiGe film becomes small as it approaches the STI trench. There is a fear that such poor forming of the SiGe film in the vicinity of the FET element region end will exert a great influence on element characteristics as the size shrinking of the element advances.

A technical recognition individual to the present inventor has been described heretofore. The present invention has been made on the basis of such technical recognition individual to the present inventor.

Hereafter, two embodiments according to the present invention will be described with reference to the drawings. One of differences between the first embodiment and the second embodiment is in a method for forming a silicon migration prevention layer to prevent migration of Si atoms to the divot.

### First Embodiment

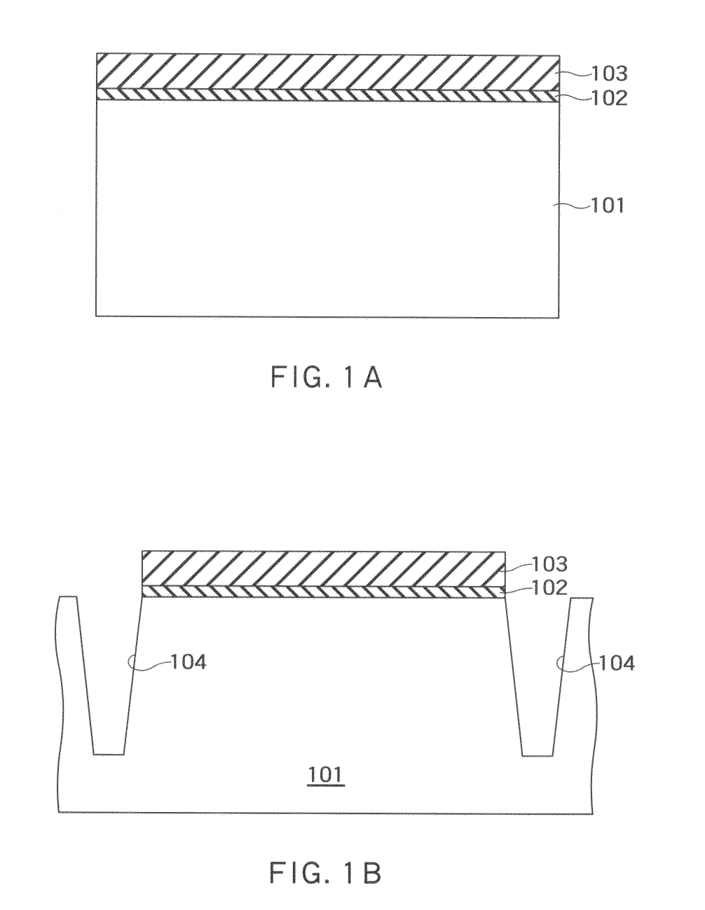

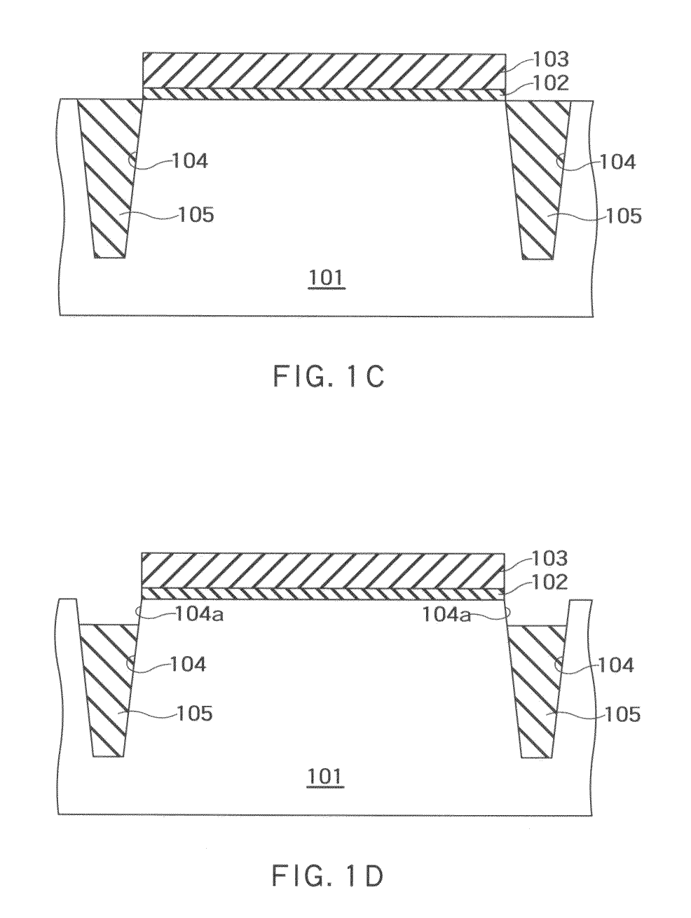

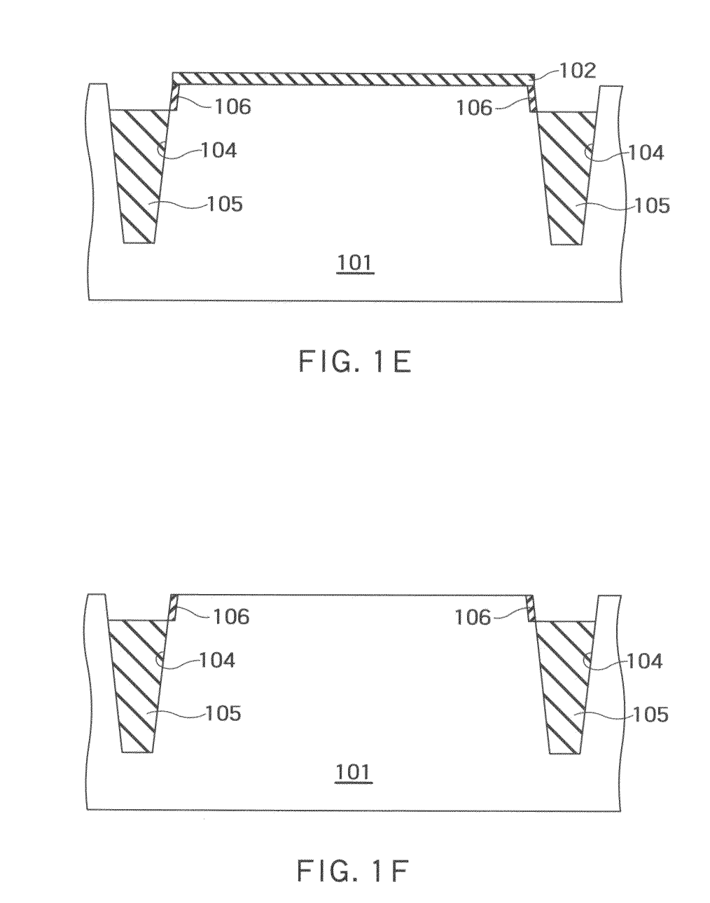

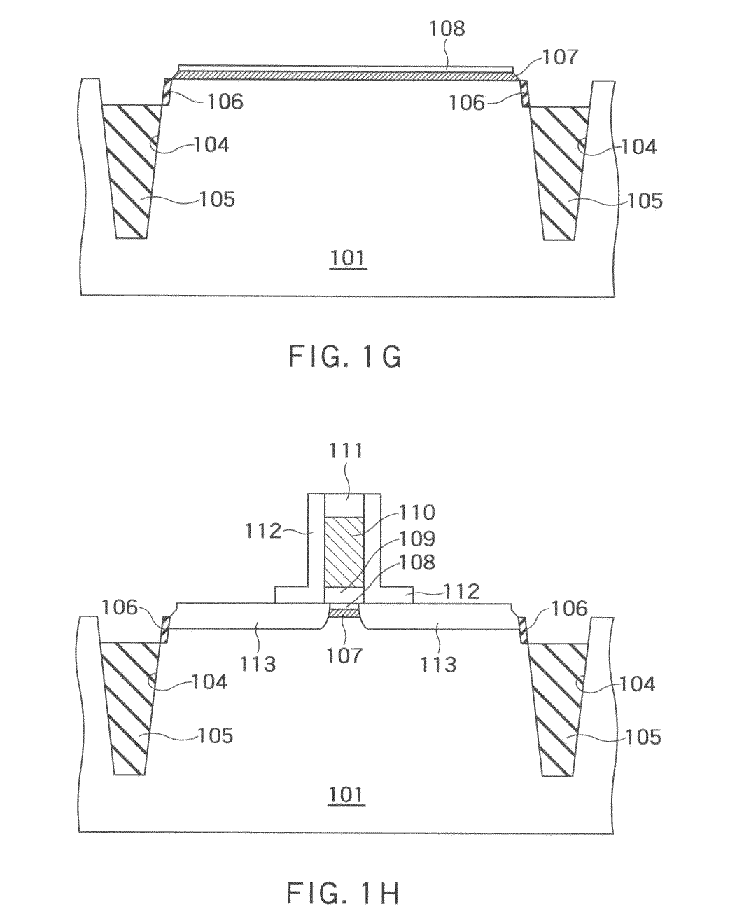

The first embodiment will now be described with reference to FIGS. 1A to 1I.

FIGS. 1A to 1I show process sectional views of a p-type FET 100 having a SiGe channel according to the present embodiment.

(1) First, as known from FIG. 1A, a silicon oxide film 102 and a silicon nitride film 103 are formed successively on a (001) plane or (011) plane of an n-type silicon substrate 101. The silicon oxide film 102 may be an insulating film other than the silicon oxide film.

By the way, the silicon nitride film 103 is a mask material for preventing the silicon oxide film 102 from being etched when etching an element isolation insulating film 105 which will be described later.

(2) Next, as known from FIG. 1B, a laminated structure film formed of the silicon oxide film 102 and the silicon nitride film 103 is patterned. Thereafter, the silicon substrate 101 is etched by anisotropic etching with the laminated structure film as a mask. As a result, a STI trench 104 for element isolation is formed. The STI trench 104 is formed so as to surround a FET element region, and the STI trench 104 partitions off the FET element region.

(3) Next, as known from FIG. 1C, a silicon oxide film is embedded in the STI trench 104 to form an element isolation insulating film 105.

(4) Next, as known from FIG. 1D, etching of the element isolation insulating film 105 is conducted and a part 104a of the side wails of the STI trench is exposed. This etching processing is conducted by wet etching using a chemical reagent such as diluted HF or dry etching using NH₃ gas or the like.

(5) Next, as known from FIG. 1E, the silicon nitride film 103 is removed by conducting etching using chemical processing or the like.

(6) Next, as known from FIG. 1E, the exposed part 104a of the side walls of the STI trench is nitrified by conducting plasma nitrifying processing and thereby a silicon migration prevention layer 106 has been formed. It is desirable that the silicon migration prevention layer 106 is formed of silicon containing nitrogen of at least 2.5×10²⁰ cm⁻³. It is desirable that the thickness of the silicon migration prevention layer 106 is at least 1 nm. Furthermore, the silicon migration prevention layer 106 may be formed of silicon containing carbon (C) instead of nitrogen, or silicon containing both nitrogen and carbon.

(7) Next, as known from FIG. 1F, the silicon oxide film 102 is removed by conducting etching. This etching processing is conducted by wet etching using a chemical agent such as diluted HF or dry etching using NH₃ gas or the like.

(8) Next, a native oxide film formed of silicon oxide or the like formed on the surface of the silicon substrate 101 is reduced and removed by conducting heat treatment (hydrogen annealing) in a reductive hydrogen atmosphere, and dangling bonds are formed on the surface of the silicon substrate. Since the dangling bonds are terminated by hydrogen atoms, the silicon atoms are brought into a state in which they migrate easily. Since the silicon migration prevention layer 106 is formed, however, the Si atoms in the FET element region do not migrate to the STI trench 104.

(9) Next, as known from FIG. 1G, epitaxial growth of a SiGe film 107 is conducted on the surface of the silicon substrate 101. The epitaxial growth of the SiGe film 107 is conducted in a reductive atmosphere (for example, hydrogen gas or silane gas) under a slightly reduced pressure (for example, in a range of 5 to 10 Torr).

(10) Next, as known from FIG. 1G, epitaxial growth of a Si cap film 108 is conducted on the SiGe film 107. The Si cap film 108 is provided to prevent oxidation or the like of the surface of the SiGe film 107 and maintain the crystalline property of the SiGe film 107. The film thickness of the Si cap film 108 is, for example, 1 nm.

(11) Next, as known from FIG. 1H, a gate insulating film 109, a gate electrode 110 and a silicon nitride film 111 serving as a mask material are deposited successively on the Si cap film 108 to form a laminated structure film. And a gate electrode structure is formed by patterning the laminated structure film. Here, as the material of the gate insulating film 109, HfSiON or HfO₂ which is a high dielectric constant material may be used besides SiO₂ or SiON. As the material of the gate electrode 110, titanium nitride (TiN), tantalum carbide (TaC), or tungsten nitride (WN) which is a metal material may be used besides polycrystalline silicon (poly-Si).

When forming the gate insulating film 109, the Si cap film 108 is oxidized and becomes a part of the gate insulating film 109 and does not remain finally, in some cases.

(12) Next, a thin silicon nitride film in the range of approximately 2 to 10 nm is deposited on the Si cap film 108 and the silicon nitride film 111. Thereafter, as known from FIG. 1H, a first side wall 112 serving as an offset spacer is formed by using lithography and anisotropic etching such as RIE. Thereafter, p-type impurities are implanted by using the ion implantation technique, and heat treatment of high temperature and short time such as RTA (Rapid Thermal Annealing) is conducted. As known from FIG. 1N, therefore, a p-type source/drain extension region 113 (diffusion layer) is formed in the silicon substrate 101. Here, for example, boron (B) or boron difluoride (BF₂) is used as p-type impurities.

(13) Next, a silicon nitride film is deposited on the Si cap film 108, the silicon nitride film 111 and the first side wall 112. Thereafter, as known from FIG. 1I, a second side wall 114 is formed by conducting anisotropic etching such as RIE. Thereafter, p-type impurities are implanted into the surface of the silicon substrate by using the ion implantation technique, and heat treatment of high temperature and short time such as RTA is conducted. As a result, a p-type source/drain region 115 (diffusion layer) is formed as known from FIG. 1I. Here, for example, boron (B) or boron difluoride (BF₂) is used as p-type impurities.

The p-type FET 100 having a SiGe channel is obtained by executing the processes heretofore described.

Thereafter, in the actual semiconductor device, a nickel mono-silicide (NiSi) film is formed on the surfaces of the source/drain contact region 115 and the gate electrode 110, and a wiring layer connected to the NiSi film is formed.

According to the present embodiment, it is possible to prevent Si atoms in the end part of the FET element region from migrating to the STI trench 104 and bring about normal epitaxial growth of the SiGe film by forming the silicon migration prevention layer 106 from the surface of the part 104a of the side wails of the STI trench to the inside as heretofore described. As a result, it is possible to suppress the dispersion of the Ge concentration in the SiGe film 107 and the film thickness of the SiGe film 107 and prevent dispersion of the threshold voltage of the FET or poor operation of the FET. As a result, it is possible to implement a FET having a SiGe channel and an excellent feature that fast operation and control of the threshold voltage are possible. In particular, the present embodiment is suitable for a FET element shrunk in size to an extent that the above-described migration range of Si atoms is not negligible as compared with the element size,

### Second Embodiment

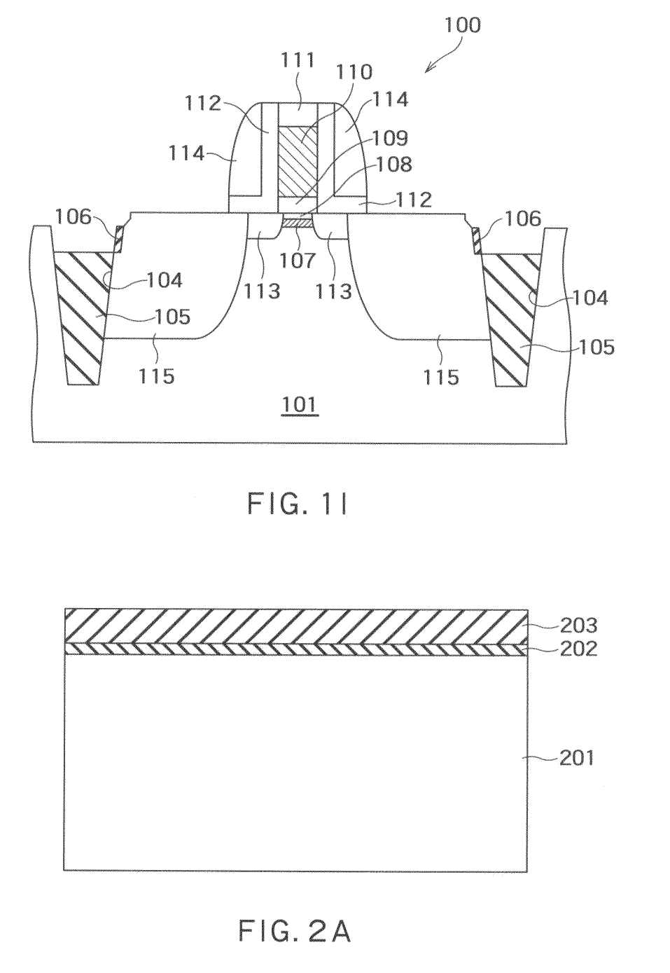

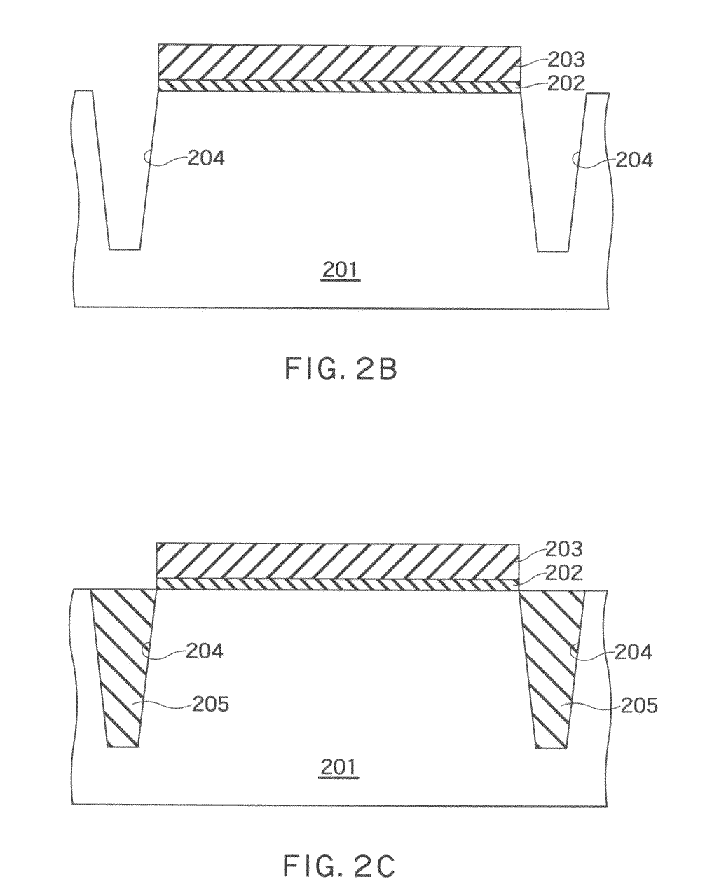

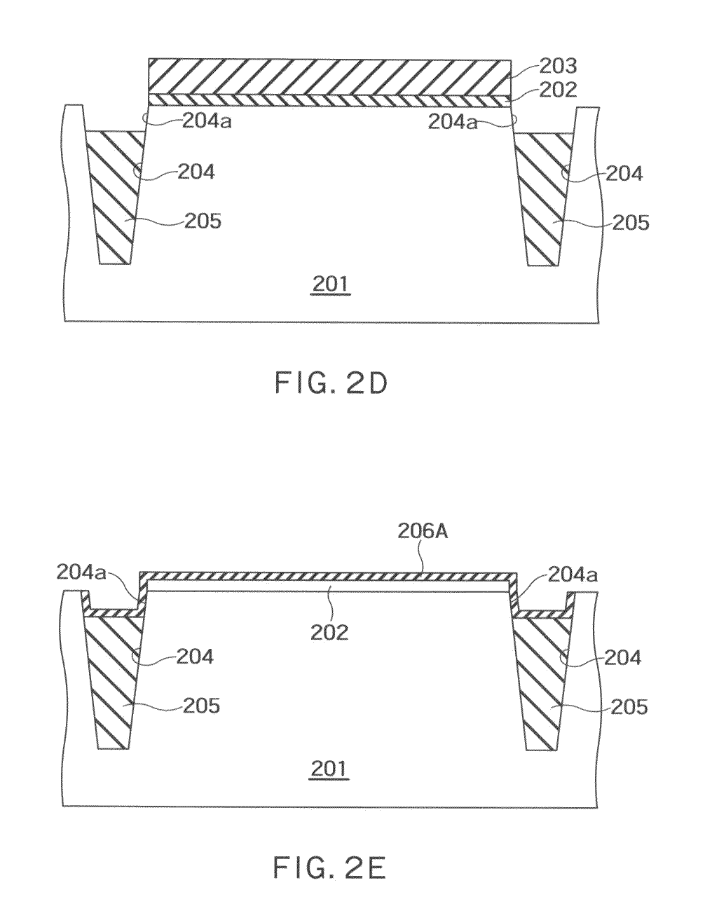

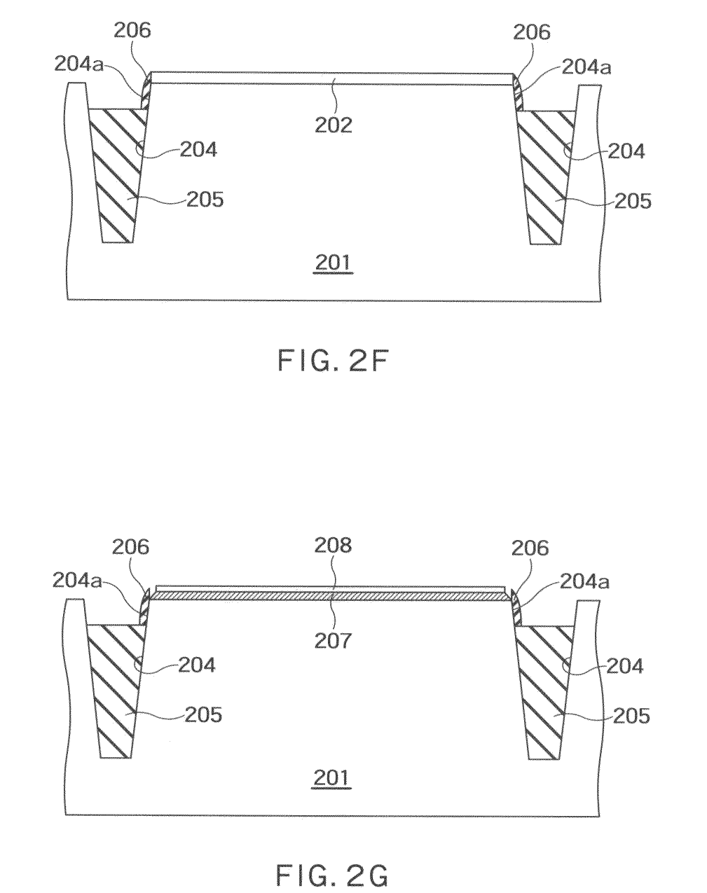

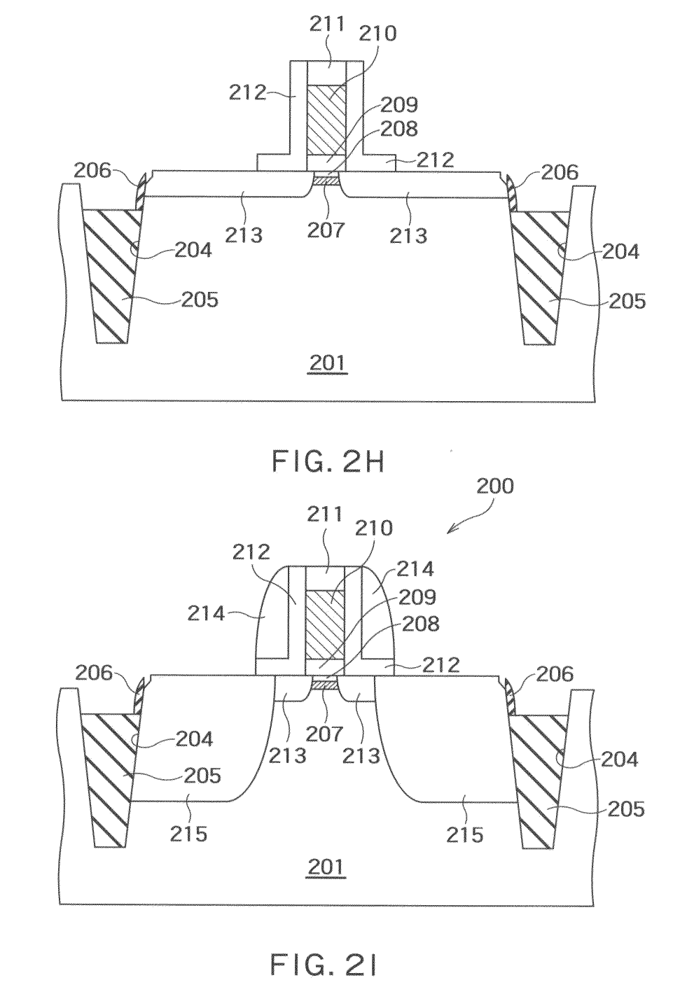

A second embodiment will now be described with reference to FIGS. 2A to 2I.

FIGS. 2A to 2I show process sectional views of a p-type FET 200 having a SiGe channel according to the present embodiment.

(1) First, as known from FIG. 2A, a silicon oxide film 202 and a silicon nitride film 203 are formed successively on a (001) plane or (011) plane of an n-type silicon substrate 201. The silicon oxide film 202 may be an insulating film other than the silicon oxide film.

By the way, the silicon nitride film 203 is a mask material for preventing the silicon oxide film 202 from being etched when etching an element isolation insulating film 205 which will be described later.

(2) Next, as known from FIG. 2B, a laminated structure film formed of the silicon oxide film 202 and the silicon nitride film 203 is patterned. Thereafter, the silicon substrate 201 is etched by anisotropic etching with the laminated structure film as a mask. As a result, a STI trench 204 for element isolation is formed. The STI trench 204 is formed so as to surround a FET element region, and the STI trench 204 partitions off the FET element region.

(3) Next, as known from FIG. 2C, a silicon oxide film is embedded in the STI trench 204 to form an element isolation insulating film 205.

(4) Next, as known from FIG. 2D, etching of the element isolation insulating film 205 is conducted and a part 204a of the side walls of the STI trench is exposed. This etching processing is conducted by wet etching using a chemical reagent such as diluted HF or dry etching using NH₃ gas or the like.

(5) Next, the silicon nitride film 203 is removed by conducting etching using chemical processing or the like.

(6) Next, as known from FIG. 2E, a silicon compound film 206A is formed on the silicon oxide film 202, the part 204a of the side walls of the STI trench and the element isolation insulating film 205. Silicon containing nitrogen (for example, Si₃N₄), silicon containing carbon (for example, SiC), or silicon containing both nitrogen and carbon (for example, SiCN) can be used as the material of the silicon compound film 206A. Furthermore, it is desirable that the silicon compound film 206A has a film thickness in the range of approximately 1 to 5 nm.

(7) Next, as known from FIG. 2F, a silicon migration prevention layer 206 is formed by conducting anisotropic etching such as the RIE on the silicon compound film 206A and leaving the silicon compound film 206A on the part 204a of the side wails of the STI trench.

(8) Next, the silicon oxide film 202 is removed by conducting etching. This etching processing is conducted by wet etching using a chemical agent such as diluted HF or dry etching using NH₃ gas or the like.

(9) Next, a native oxide film formed of silicon oxide or the like formed on the surface of the silicon substrate 201 is reduced and removed by conducting heat treatment (hydrogen annealing) in a reductive hydrogen atmosphere, and dangling bonds are formed on the surface of the silicon substrate. Since the dangling bonds are terminated by hydrogen atoms, the silicon atoms are brought into a state in which they migrate easily. Since the silicon migration prevention layer 106 is formed, however, the Si atoms in the FET element region do not migrate to the STI trench 204.

(10) Next, as known from FIG. 2G, epitaxial growth of a SiGe film 207 is conducted on the surface of the silicon substrate 201. The epitaxial growth of the SiGe film 207 is conducted in a reductive atmosphere (for example, hydrogen gas or silane gas) under a slightly reduced pressure (for example, in a range of 5 to 10 Torr).

(11) Next, as known from FIG. 2G, epitaxial growth of a Si cap film 208 is conducted on the SiGe film 207. The Si cap film 208 is provided to prevent oxidation or the like of the surface of the SiGe film 207 and maintain the crystalline property of the SiGe film 207. The film thickness of the Si cap film 208 is, for example, 1 nm.

(12) Next, as known from FIG. 2H, a gate insulating film 209, a gate electrode 210 and a silicon nitride film 211 serving as a mask material are deposited successively on the Si cap film 208 to form a laminated structure film. And a gate electrode structure is formed by patterning the laminated structure film. Here, as the material of the gate insulating film 209, HfSiON or HfO₂ which is a high dielectric constant material may be used besides SiO₂ or SiON. As the material of the gate electrode 210, titanium nitride (TiN), tantalum carbide (TaC), or tungsten nitride (WN) which is a metal material may be used besides polycrystalline silicon (poly-Si).

When forming the gate insulating film 209, the Si cap film 208 is oxidized and becomes a part of the gate insulating film 209 and does not remain finally, in some cases.

(13) Next, a thin silicon nitride film in the range of approximately 2 to 10 nm is deposited on the Si cap film 208 and the silicon nitride film 211. Thereafter, as known from FIG. 2H, a first side wall 212 serving as an offset spacer is formed by using lithography and anisotropic etching such as RIE. Thereafter, p-type impurities are implanted by using the ion implantation technique, and heat treatment of high temperature and short time such as the RTA is conducted. As known from FIG. 2H, therefore, a p-type source/drain extension region 213 (diffusion layer) is formed in the silicon substrate 201. Here, for example, boron (B) or boron difluoride (BF₂) is used as p-type impurities.

(14) Next, a silicon nitride film is deposited on the silicon substrate 201, the silicon nitride film 211 and the first side wall 212. Thereafter, as known from FIG. 21, a second side wall 214 is formed by conducting anisotropic etching such as RIE. Thereafter, p-type impurities are implanted into the surface of the silicon substrate by using the ion implantation technique, and heat treatment of high temperature and short time such as RTA is conducted. As a result, a p-type source/drain contact region 215 (diffusion layer) is formed as known from FIG. 2I. Here, for example, boron (B) or boron difluoride (BF₂) is used as p-type impurities.

The p-type FET 200 having a SiGe channel is obtained by executing the processes heretofore described.

Thereafter, in the actual semiconductor device, a nickel mono-silicide (NiSi) film is formed on the surfaces of the source/drain contact region 215 and the gate electrode 210, and a wiring layer connected to the NiSi film is formed.

According to the present embodiment, it is possible to prevent Si atoms in the end part of the FET element region from migrating to the STI trench 204 and bring about normal epitaxial growth of the SiGe film by forming the silicon migration prevention layer 206 so as to cover the part 204a of the side wails of the STI trench, as heretofore described. As a result, it is possible to suppress the dispersion of the Ge concentration in the SiGe film 207 and the film thickness of the SiGe film 207 and prevent dispersion of the threshold voltage of the FET or poor operation of the FET. As a result, it is possible to implement a FET having a SiGe channel and an excellent feature that fast operation and control of the threshold voltage are possible. In particular, the present embodiment is suitable for a FET element shrunk in size to an extent that the above-described migration range of Si atoms is not negligible as compared with the element size.

Heretofore, the two embodiments according to the present invention have been described. However, it is also possible to take a different embodiment within the scope of the technical thought of the present invention.

As for formation of the silicon migration prevention layer 106 (206), for example, the element isolation insulating film 105 (205) may be embedded after forming the STI trench 104 (204) and forming the silicon migration prevention layer 106 (206) at least above the side wails of the STI trench, besides the above-described method.

As the silicon substrate 101 or 201, not only the substrate (Si substrate) formed of only silicon but also a semiconductor substrate containing silicon as its main component may be used. For example, a SOI substrate having SiO₂ inserted between the Si substrate and a surface Si layer, or a strained SOI substrate (sSOI substrate) having SiO₂ between the Si substrate and a surface strained Si layer may be used. Besides, a substrate having strained SiGe and relaxed SiGe between the Si substrate and a surface strained Si layer may be used.

The semiconductor device according to the present invention is not restricted to the p-type FET, but may be an n-type FET. In this case, a p-type semiconductor substrate is used in the same way as the ordinary FET or a p-well is formed in the semiconductor substrate and a FET is fabricated therein. The n-type source/drain diffusion layer is formed by implanting n-type impurities (for example, As or P) by using the ion implantation technique and then conducting heat treatment.

Additional advantages and modifications will readily occur to those skilled in the art.

Therefore, the invention in its broader aspects is not: limited to the specific details and representative embodiments shown and described herein.

Accordingly, various modifications may be made without departing the spirit or scope of the general inventive concepts as defined by the appended claims and their equivalents.

1. A semiconductor device comprising:
a substrate having silicon as a main component;
a trench which is formed in the substrate in a thickness direction, which partitions off an element region where a semiconductor element is formed, and which has a side wall surface connected to the surface of the substrate in the element region;
an element isolation insulating film embedded in the trench up to a middle of the trench;
a silicon migration prevention layer which exists between the surface of the substrate in the element region and the side wall surface covered by the element isolation insulating film, and which contains at least one of nitrogen and carbon; and
a SiGe film formed on the substrate in the element region.

2. The semiconductor device according to claim 1, wherein the silicon migration prevention layer comprises SiC, SiCN, Si₃N₄, or silicon containing nitrogen of at least 2.5×10²⁰ cm⁻³.

3. The semiconductor device according to claim 1, wherein the silicon migration prevention layer is a layer having a predetermined thickness formed in a state in which the silicon migration prevention layer has embedded in the side wall surface of the trench.

4. The semiconductor device according to claim 3, wherein the predetermined thickness of the silicon migration prevention layer is at least 1 nm.

5. The semiconductor device according to claim 3, further comprising:
a gate insulating film formed above the SiGe film;
a gate electrode formed on the gate insulating film; and
a source diffusion layer and a drain diffusion layer formed in the substrate in the element region,
wherein the SiGe film is configured as a channel between the source diffusion layer and the drain diffusion layer.

6. The semiconductor device according to claim 5, wherein the gate insulating film comprises a high dielectric constant material, and the gate electrode comprises a metal material.

7. The semiconductor device according to claim 1, wherein the silicon migration prevention layer is a layer having a predetermined thickness formed on the side wall surface of the trench.

8. The semiconductor device according to claim 7, wherein the predetermined thickness of the silicon migration prevention layer is at least 1 nm.

9. The semiconductor device according to claim 7, further comprising:
a gate insulating film formed above the SiGe film;
a gate electrode formed on the gate insulating film; and
a source diffusion layer and a drain diffusion layer formed in the substrate in the element region,
wherein the SiGe film is configured as a channel between the source diffusion layer and the drain diffusion layer.

10. The semiconductor device according to claim 9, wherein the gate insulating film comprises a high dielectric constant material, and the gate electrode comprises a metal material.

11. A semiconductor device manufacturing method comprising:
forming a mask material on a substrate having silicon as a main component;
patterning the mask material;
forming a trench which partitions off an element region, by etching the substrate with the mask material used as a mask;
forming an element isolation insulating film by embedding an insulating film into the trench;
exposing a part of a side wall of the trench by etching the element isolation insulating film;
forming a silicon migration prevention layer embedded in the part of the side wall of the trench by nitrifying and/or carbonizing the exposed part of the side wall of the trench;
removing the mask material and then reducing a native oxide film on a surface of the substrate by hydrogen annealing; and
then epitaxially growing a SiGe film on the substrate in the element region.

12. The semiconductor device manufacturing method according to claim 11, comprising:
forming a first mask material formed of a silicon oxide film and a second mask material formed of a silicon nitride film, successively as the mask material;
using a silicon oxide film as the insulating film embedded in the trench;
etching the element isolation insulating film and then removing the second mask material; and
forming the silicon migration prevention layer and then removing the first mask material.

13. The semiconductor device manufacturing method according to claim 11, wherein the silicon migration prevention layer is formed as a layer having a thickness of at least 1 nm.

14. The semiconductor device manufacturing method according to claim 11, further comprising:
forming a silicon film on the SiGe film;
forming a gate insulating film on the silicon film;
forming a gate electrode on the gate insulating film; and
forming a source diffusion layer and a drain diffusion layer in the substrate in the element region.

15. The semiconductor device manufacturing method according to claim 14, wherein a high dielectric constant material is used as the gate insulating film and a metal material is used as the gate electrode.

16. A semiconductor device manufacturing method comprising:
forming a mask material on a substrate having silicon as a main component;
patterning the mask material;
forming a trench which partitions off an element region, by etching the substrate with the mask material used as a mask;
forming an element isolation insulating film by embedding an insulating film into the trench;
exposing a part of a side wall of the trench by etching the element isolation insulating film;
forming a silicon compound film on the mask material, the part of the side wall of the trench, and the element isolation insulating film;
etching the silicon compound film by using anisotropic etching, and thereby leaving the silicon compound film above the part of the side wall of the trench as a silicon migration prevention layer;
removing the mask material and then reducing a native oxide film on a surface of the substrate by hydrogen annealing; and
then epitaxially growing a SiGe film on the substrate in the element region.

17. The semiconductor device manufacturing method according to claim 16, comprising:
forming a first mask material formed of a silicon oxide film and a second mask material formed of a silicon nitride film, successively as the mask material;
using a silicon oxide film as the insulating film embedded in the trench;
etching the element isolation insulating film and then removing the second mask material; and
forming the silicon migration prevention layer and then removing the first mask material.

18. The semiconductor device manufacturing method according to claim 16, wherein the silicon migration prevention layer is formed as a layer having a thickness of at least 1 nm.

19. The semiconductor device manufacturing method according to claim 16, further comprising:
forming a silicon film on the SiGe film;
forming a gate insulating film on the silicon film;
forming a gate electrode on the gate insulating film; and
forming a source diffusion layer and a drain diffusion layer in the substrate in the element region.

20. The semiconductor device manufacturing method according to claim 19, wherein a high dielectric constant material is used as the gate insulating film and a metal material is used as the gate electrode.
